(19) United States
(12) Patent Application Publication
(10) Pub. No.: US 2010/0154866 A1
(43) Pub. Date: Jun. 24, 2010

(54) HYBRID SOLAR POWER SYSTEM

(76) Inventor: Sitara R. Khan, Old Westbury, NY (US)

Correspondence Address: DARBY & DARBY P.C., P.O. BOX 770, Church Street Station, New York, NY, 10008-0770, US

(21) Appl. No.: 12/641,204

(22) Filed: Dec. 17, 2009

Related U.S. Application Data
(63) Continuation of application No. 12/431,725, filed on Apr. 28, 2009, now abandoned.
(60) Provisional application No. 61/048,547, filed on Apr. 28, 2008.

(51) Int. Cl. H01L 31/058

(52) U.S. Cl. 136/248

(57) ABSTRACT

A hybrid solar power system incorporates both solar thermal technology and photovoltaic technology in producing power. The hybrid solar power system includes a cover, thermal layers, and photovoltaic layers disposed within an enclosure. The hybrid solar power system is arranged to produce power thermally via the thermal layers and directly via the photovoltaic layers. In producing the power, the thermal layers and the photovoltaic layers first harness sunlight incident on the hybrid solar power system. Subsequently, the inner surfaces of the enclosure include reflective surfaces, reflecting the incident sunlight back through the thermal layers and the photovoltaic layers so that additional power can be generated from the reflected light.

### CROSS REFERENCE TO RELATED APPLICATIONS

This application claims priority to U.S. Provisional Application Ser. No. 61/048,547, filed Apr. 28, 2008, entitled “High Surface Area Solar Panel,” the contents of which are incorporated herein by reference in its entirety.

### FIELD OF INVENTION

The present invention generally relates to renewable energy, and more specifically to solar power generation via solar thermal and photovoltaic technologies.

### BACKGROUND OF THE INVENTION

Hybrid systems for solar (renewable) energy utilization have attracted considerable attention from scientists and engineers during the last decade because of their higher efficiency and stability of performance in comparison to individual solar devices. However, new and efficient methods are still necessary to capture more and more of the sun's energy.

### SUMMARY OF THE INVENTION

The invention relates to a hybrid solar power system that includes an enclosure having at least one reflective surface, at least one cover having at least one optical feature, at least one thermal layer disposed in the enclosure, each of the at least one thermal layer having a plurality of thermal conduits; and at least one layer of photovoltaic solar cells disposed in the enclosure, each of the at least one layer of photovoltaic cells having a plurality of photovoltaic cells. Further, the one layer of thermal tubing and the at least one layer of photovoltaic solar cells are configured so that both layers are exposed to an incident light.

### BRIEF DESCRIPTION OF THE DRAWINGS

The present invention will be more readily understood from the detailed description of exemplary embodiments presented below considered in conjunction with the accompanying drawings, in which:

FIG. 1 illustrates a cross sectional view of a hybrid solar power system according to an embodiment of the present invention;

FIG. 2 is an exploded perspective view of the hybrid solar power system of FIG. 1 according to an embodiment of the present invention;

FIG. 3 is an exemplary illustration showing each of the thermal layers and the photovoltaic layers are exposed to the incident light, and the subsequent reflected light;

FIG. 4A is a front view of a solar panel in accordance with an embodiment of the present invention;

FIG. 4B is an isometric view thereof;

FIG. 5A is a front view of a solar panel in accordance with a second embodiment of the present invention;

FIG. 5B is an isometric view thereof;

FIG. 6A is a front view of a solar panel in accordance with a third embodiment of the present invention;

FIG. 6B is an isometric view thereof;

FIG. 7A is a front view of a solar panel in accordance with a fourth embodiment of the present invention;

FIG. 7B is an isometric view thereof;

FIG. 8A is a front view of a solar panel in accordance with a fifth embodiment of the present invention;

FIG. 8B is an isometric view thereof;

FIG. 9A is a front view of a solar panel in accordance with a sixth embodiment of the present invention;

FIG. 9B is an isometric view thereof;

FIG. 10A is a top view of a solar panel in accordance with a seventh embodiment of the present invention;

FIG. 10B is a cross-sectional view thereof;

FIG. 11A is a top view of a solar panel in accordance with an eighth embodiment of the present invention;

FIG. 11B is a cross-sectional view thereof;

FIG. 12A is an isometric view of a solar panel in accordance with a ninth embodiment of the present invention;

FIG. 12B is a cross-sectional view thereof;

FIGS. 13A-13C are side views of solar cells in accordance with respective embodiments of the present invention;

FIGS. 14A-14C illustrate the incidence of solar radiation on a solar panel in accordance with an embodiment of the present invention;

FIG. 15 is a cross-sectional view of a solar panel in accordance with a tenth embodiment of the present invention;

FIGS. 16A and 16B illustrate a movable mount for a solar panel in accordance with an embodiment of the present invention;

FIG. 17 is a front view a solar detector and solar panel in accordance with an embodiment of the present invention;

FIG. 18A is an isometric view of a solar panel in accordance with a eleventh embodiment of the present invention;

FIG. 18B is a front view thereof;

FIG. 19A is an isometric view of a solar panel in accordance with a twelfth embodiment of the present invention;

FIG. 19B is a front view thereof;

FIG. 20A is an isometric view of a solar panel in accordance with a thirteenth embodiment of the present invention;

FIG. 20B is a front view thereof; and

FIG. 21 is a top view of a solar panel in accordance with a fourteenth embodiment of the present invention.

### DETAILED DESCRIPTION

The present invention is directed to a hybrid solar power system.

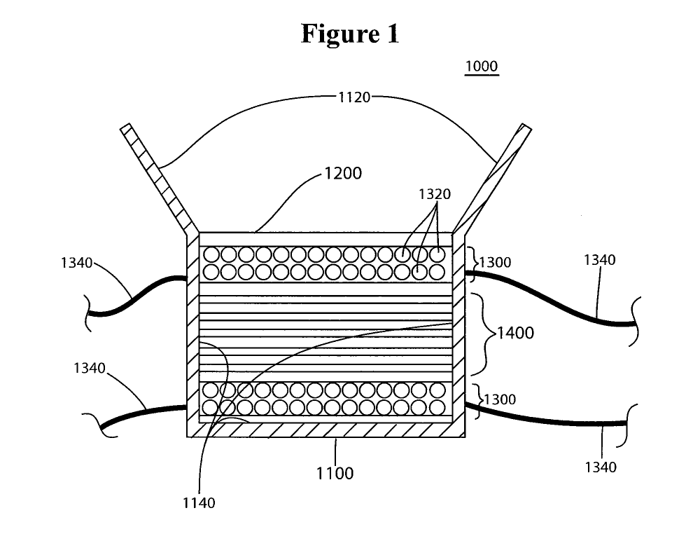

FIG. 1 shows a cross sectional view of a hybrid solar power system 1000 according to an embodiment of the present invention. The hybrid solar power system 1000 incorporates both solar thermal technology and photovoltaic technology in producing power. The hybrid solar power system 1000 includes a cover 1200, thermal layers 1300, and photovoltaic layers 1400 disposed within an enclosure 1100. The hybrid solar power system 1000 is arranged to produce power thermally via the thermal layers 1300 and directly via the photovoltaic layers 1400. In producing the power, the thermal layers 1300 and the photovoltaic layers 1400 first harness sunlight incident on the hybrid solar power system 1000. Subsequently, the inner surfaces of the enclosure 1100 include reflective surfaces 1140, reflecting the incident sunlight back through the thermal layers 1300 and the photovoltaic layers 1400 so that additional power can be generated from the reflected light. The reflective surfaces 1140 may be parabolic, convex, concave, or any other design that can focus the incident light energy onto the thermal layers 1300 and the photovoltaic layers 1400. Additionally, the top portions 1120 of the enclosure 1100 are configured to capture additional light and focus it onto the thermal layers 1300 and the photovoltaic layers 1400 so that the apparatus can capture a larger area of incident sunlight than the actual footprint of the hybrid solar power system 1000.

In addition to the top portions 1120 and the reflective surfaces 1140, the cover 1200 also includes optical features to increase the efficiency of the hybrid solar power system 1000. The cover 1200 may include an arrangement of optical features such as lenses, prisms, Fresnel lenses, or any other optical feature designed to focus and intensify the incident sunlight onto the thermal layers 1300 and the photovoltaic layers 1400. These optical features may be incorporated as various designs, including having the features be on a microscopic level, depending on the specific application of the hybrid solar power system 1000.

In generating thermal power, each of the thermal layers 1300 includes conduits 1320. The conduits 1320 carry a thermal heat-transfer medium that is heated by the incident and reflected sunlight. Although the heat-transfer medium may include any gas, liquid, etc. capable of absorbing thermal energy from the sunlight and being passed through the conduits 1320, the heat-transfer medium is preferably water for both its thermal and optical properties. The heat-transfer medium is transported to and from the hybrid solar power system 1000 via piping 1340. The conduits 1320 are transparent so that the energy of the light not captured initially can pass through each of the thermal layers 1300, allowing the sunlight to reach each of the thermal layers 1300 and the photovoltaic layers 1400, and be reflected through the thermal layers 1300 and the photovoltaic layers 1400 again. Additionally, the conduits 1320 may be designed to have optical features such as lenses, prisms, etc. to increase the efficiency of the thermal layers 1300 and to focus the light onto the medium being passed through the conduits 1320. Alternatively, the conduits 1320 may include high-surface area solar panels to capture as much sunlight as possible to heat the heat-transfer medium. Exemplary high-surface area solar panels are described in further detail below.

As noted above, in addition to the thermal layers 1300, the hybrid solar power system 1000 includes photovoltaic layers 1400 to generate additional power. Each of the photovoltaic layers 1400 is made up of an array of photovoltaic cells. The photovoltaic cells directly converts the sunlight into electricity. Similar to the thermal layers 1300, the photovoltaic layers 1400 are also transparent, allowing the incident sunlight to pass through the photovoltaic layers 1400 and be reflected by the reflective surfaces 1140 of the enclosure 1100. Furthermore, although the photovoltaic layers 1400 are shown as flat panels, the layers may take different shapes to increase the amount of effective surface area of the photovoltaic layers 1400. For example, the layers may be wavy, angular, etc. In addition to increasing the surface area of each photovoltaic layer, each of the photovoltaic cells that make up the photovoltaic layers 1400 may be designed to maximize the amount of surface area used for converting the light energy into electricity. As noted above, such high-surface area solar cells are discussed in greater detail below.

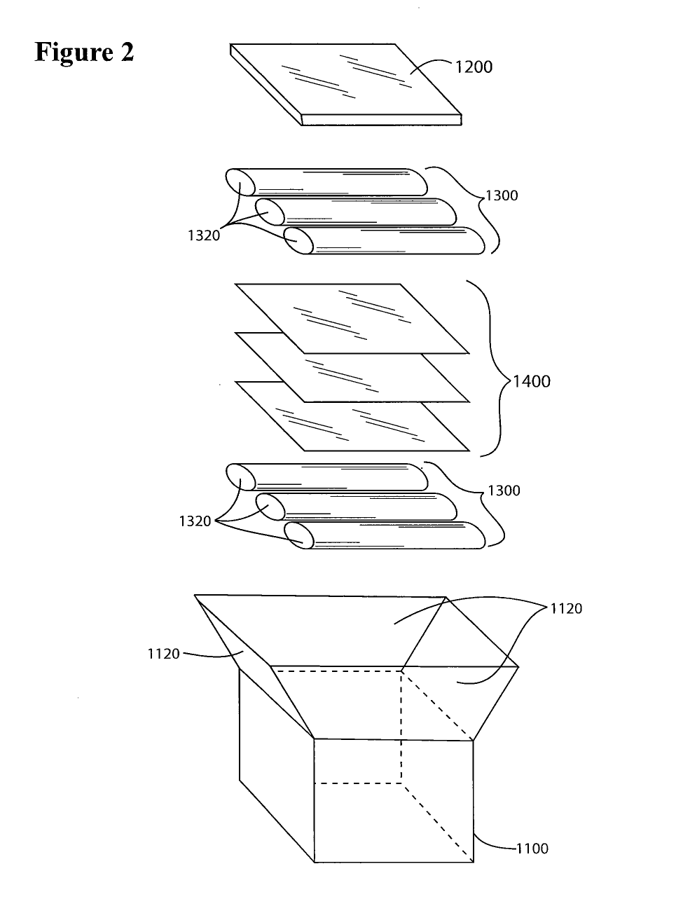

FIG. 2 is an exploded perspective view 2000 of the hybrid solar power system 1000 according to an embodiment of the present invention. The exploded view 2000 illustrates the components that make up the hybrid solar power system 1000. The exploded view 2000 includes the enclosure 1100, with top portions 1120, the thermal layers 1300, the photovoltaic layers 1400, and the cover 1200. Although the exploded view is show with only two thermal layers 1300 and three photovoltaic layers 1400, the hybrid solar power system 1000 may be implemented with any number of thermal layers 1300 and photovoltaic layers 1400. Further, the enclosure 1100 may be in the form of other shapes, and is not limited to the rectangular shape shown in the exploded view 2000.

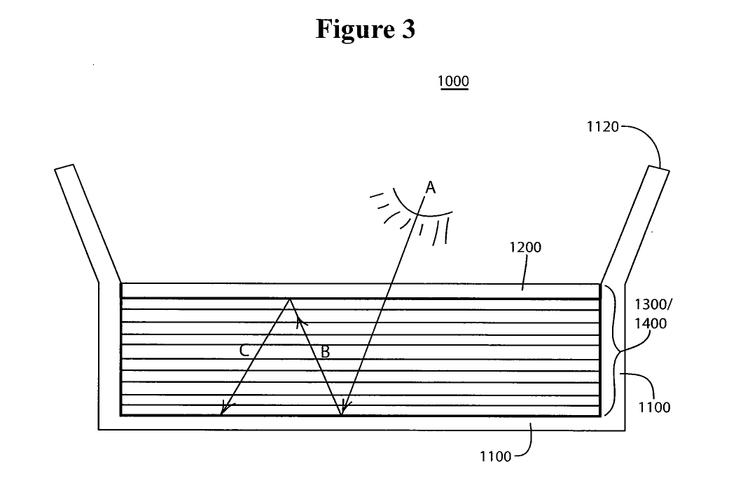

FIG. 3 is a simplified cross-sectional view of the hybrid solar power system 1000 according to an embodiment of the present invention. FIG. 3 shows the enclosure 1100 with reflective surfaces 1120, and lines representing at least one of the thermal layers 1300 and the photovoltaic layers 1400. The simplified view of FIG. 3 shows a simple diagram of how the thermal layers 1300 and photovoltaic layers 1400 are exposed to an incident sunlight (A), allowing the incident sunlight (A) to pass through each layer and is subsequently reflected within the hybrid solar power system 1000. As shown in FIG. 3, the incident sunlight (A) is passes through the thermal layers 1300 and photovoltaic layers 1400 and is reflected by the reflective surface 1120 of the enclosure 1100. The reflected light (B) may also be reflected by the inner surface of the cover 1200 (reflected light C). Accordingly, each of the thermal layers 1300 and the photovoltaic layers 1400 are exposed to the incident light (A), and the subsequent reflected light, e.g., reflected light (B), and reflected light (C) for the exemplary illustration shown in FIG. 3. Any sunlight incident on the hybrid solar power system 1000 can be reflected by any of the interior surfaces of the enclosure 1100 and the cover 1200. Accordingly, the thermal layers 1300 and the photovoltaic layers 1400 are exposed to an incident sunlight and many subsequent reflections.

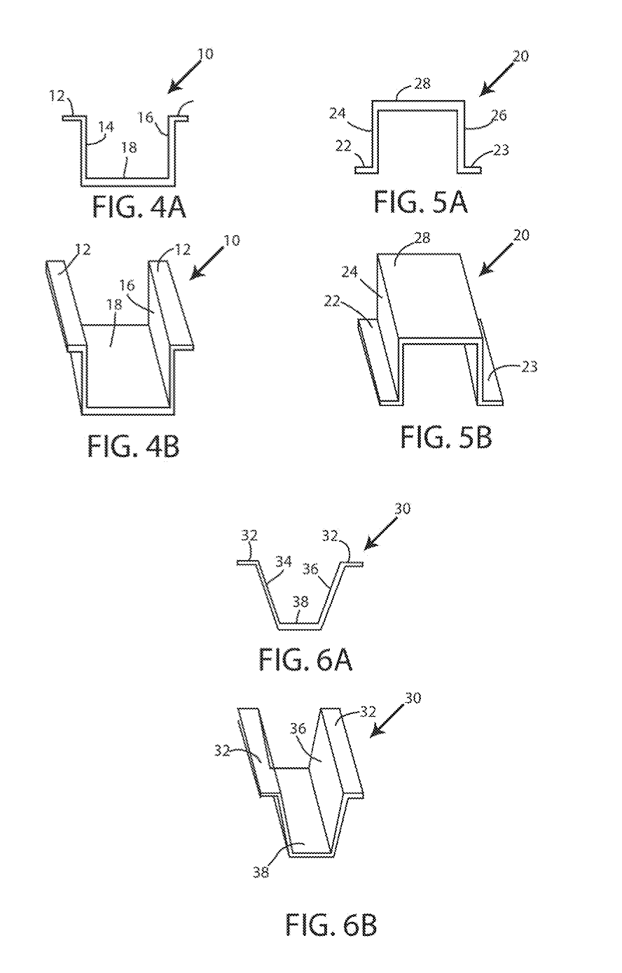

FIGS. 4-12, 15, and 18-21 illustrate various shapes of high-surface area solar panels according to various embodiments of the present invention. As noted above, these high-surface area solar panels may be implemented in the thermal layers 1300 or the photovoltaic layers 1400 of the hybrid solar power system 1000. The solar panels are shaped in order to increase the surface area of the panels, and the amount of solar energy captured by the solar panels, which can improve the function of the solar panels and the electrical energy output.

Referring now to FIGS. 4A and 4B, a concave square shaped solar panel 10 is shown. The solar panel 10 includes upper solar collecting surfaces 12, vertical solar collecting surfaces 14 and 16, and a horizontal solar collecting surface 18.

The solar collecting surfaces of the panels may be covered in conventional silicon based solar cells (photovoltaic cells). The semiconductor wafers can be covered by a protective sheet (e.g., glass) to protect the wafers from the elements while still allowing light to pass. The solar cells can be connected in series in modules, which can then be interconnected in series or parallel to create a solar array. Alternative types of solar collection mediums and systems may also be used. For example, thin film type solar collection technologies may be used. In addition, other various materials can be used, such as cadmium telluride, copper-indium selenide, or other suitable materials can be used. The invention is not limited to a particular solar technology or material. The solar collection medium can also be solid, as well as liquid and gaseous, and any combinations thereof.

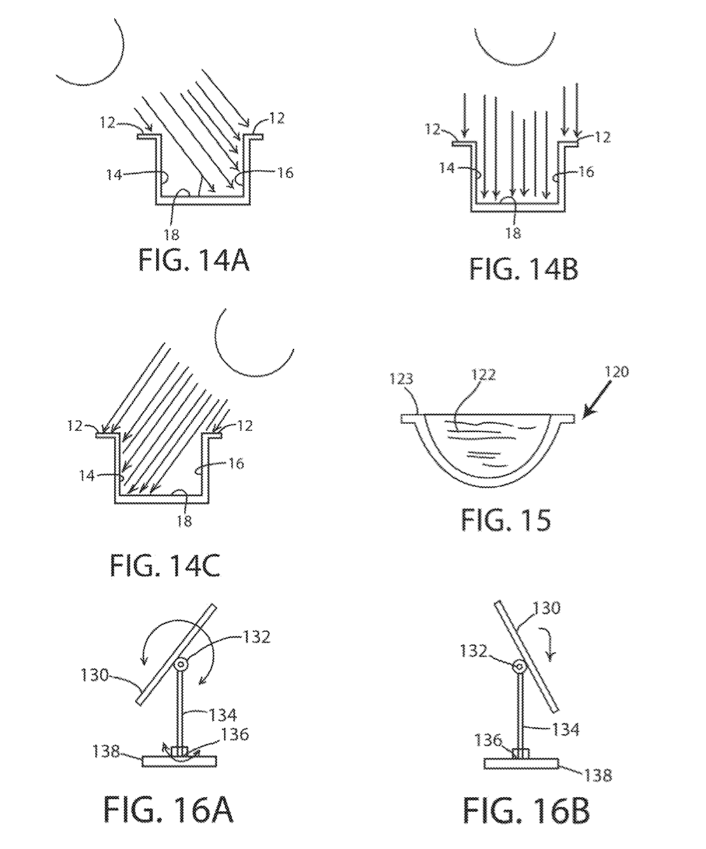

The shape of the solar panel 10 is designed such that solar rays will be incident on the various solar collecting surfaces 12, 14, 16, and 18 as the sun moves across the sky. As shown in FIGS. 14A-14C, as the sun moves across the sky during the course of a day, the various solar collecting surfaces receives the sun's rays. In one example, the solar panel 10 is arranged such that early in the day, when the sun is low in the sky as it is rising from the East (FIG. 14A), solar collecting surfaces 12, 18, and 16 receive solar rays, which results in the conversion to electricity. When the sun is high in the sky and directly overhead (FIG. 14B), solar collecting surfaces 12 and 18 receive the solar rays. Finally, when the sun is low in the sky and setting in the West (FIG. 14C), solar collecting surfaces 12, 14, and 18 receive solar radiation. In particular, solar surfaces 14 and 16 help to increase the amount of solar energy collected when the sun is in the sky. Thus, for example, if a number of solar panels having the shape of solar panel 10 were placed on a surface of limited square footage (e.g., a roof), the effective surface area of the solar panels is increase because the vertical walls 14 and 16 increase the surface area exposed to the sun without taking up the limited square footage on a roof, which allows for more solar energy to be collected as compared to flat panels.

Referring now to FIGS. 5A and 5B, a convex square shaped solar panel 20 is shown. The solar panel 20 is designed such that the various solar collection surfaces 22, 23, 24, 26, and 28 will collect the sun's rays in an efficient manner as the sun moves across the sky. For example, the solar panel 20 can be arranged such that solar collecting surfaces 22, 24, and 28 will collect the sun's rays as is rises, surfaces 22, 28, and 23 will collect the sun's rays as it is overhead, and surfaces 28, 26, and 23 will collect the sun's rays as it sets.

Referring now to FIGS. 6A and 6B, a concave angle-walled solar panel 30 is shown. The solar panel 30 is designed such that the various solar collection surfaces 32, 34, 36, and 38 will collect the sun's rays in an efficient manner as the sun moves across the sky. Since the solar collection surfaces 34 and 36 are angled, these surfaces will collect the sun's rays when it is directly overhead, in addition to the horizontal surfaces 32 and 38. Further, the solar collecting surfaces 34 and 36 can be at such an angle such that when the sun is low in the sky, the rays can be incident to the surfaces and a nearly 90 degree angle, which can improve the collection efficiency of the surfaces. The solar panel 30 can be arranged, for example, such that solar collecting surfaces 32, 36, and 38 will collect the sun's rays as is rises, surfaces 32, 34, 38, and 36 will collect the sun's rays as it is overhead, and surfaces 32, 34, and 38 will collect the sun's rays as it sets.

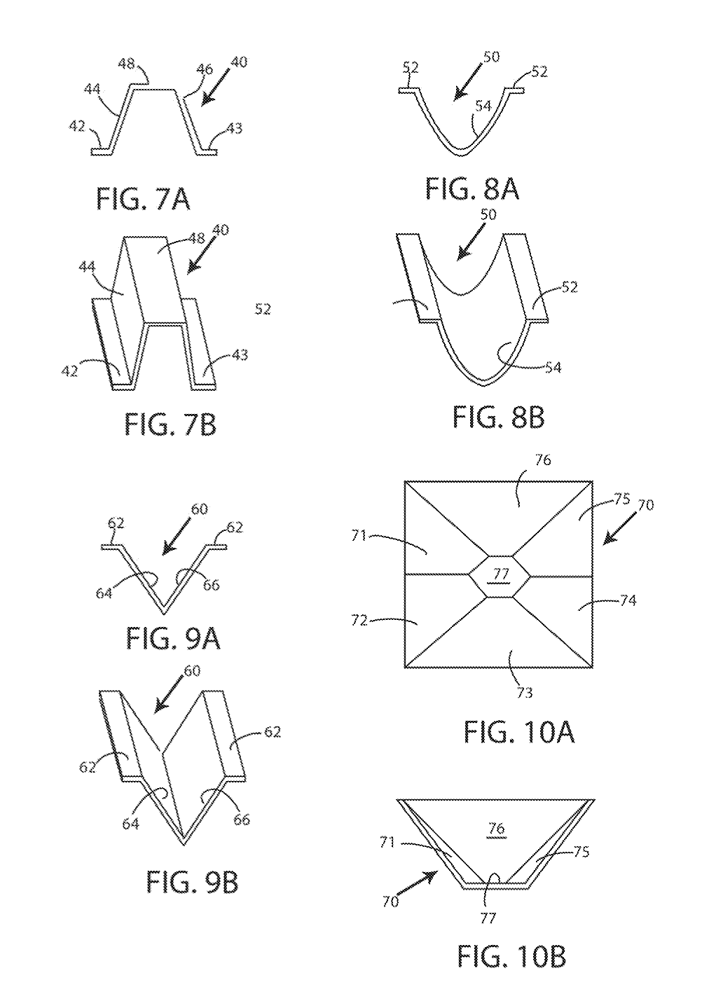

Referring now to FIGS. 7A and 7B, a convex angle-walled solar panel 40 is shown. The solar panel 40 is designed such that the various solar collection surfaces 42, 43, 44, 46 and 48 will collect the sun's rays in an efficient manner as the sun moves across the sky. Since the solar collection surfaces 44 and 46 are angled, these surfaces will collect the sun's rays when it is directly overhead, in addition to the horizontal surfaces 42, 43, and 48. Further, the solar collecting surfaces 44 and 46 can be at such an angle such that when the sun is low in the sky, the rays can be incident to the surfaces and a nearly 90 degree angle, which can improve the collection efficiency of the surfaces. The solar panel 40 can be arranged, for example, such that solar collecting surfaces 42, 44, and 48 will collect the sun's rays as is rises, surfaces 42, 44, 48, 46 and 43 will collect the sun's rays as it is overhead, and surfaces 43, 46, and 48 will collect the sun's rays as it sets.

Referring now to FIGS. 8A and 8B, a concave curved solar panel 50 is shown. The solar panel 50 is designed such that the various solar collection surfaces 52 and 54 will collect the sun's rays in an efficient manner as the sun moves across the sky. Since the solar collection surface 54 is curved, different parts of this surface will collect the sun's rays as it moves across the sky. A convex curved solar panel (not show) may also be used. The shape of the curved collection surface 54 can be varied to achieve optimum efficiency. For example, the curved surface can be semicircular, parabolic, elliptical, or any other curved shape.

Referring now to FIGS. 9A and 9B, a concave triangular solar panel 60 is shown. The solar panel 60 is designed such that the various solar collection surfaces 62, 64, and 66 will collect the sun's rays in an efficient manner as the sun moves across the sky. As compared to solar panel 30, solar panel 60 lacks an equivalent bottom horizontal collection surface 38. However, angled surfaces 64 and 66 have a larger surface area as compared to angled surfaces 34 and 36, and can be provided at less steep angles such that when the sun is directly overhead surface 64 and 66 can efficiently collect the sun's rays. A convex triangular solar panel (not show) may also be used.

Referring now to FIGS. 10A and 10B, a concave seven-surfaced square solar panel 70 is shown. The solar panel 70 is designed such that the various solar collection surfaces 71-77 will collect the sun's rays in an efficient manner as the sun moves across the sky. Since the solar panel 70 has solar collection surfaces arranged 360 degrees around the solar panel 70, the solar panel 70 can be installed with out particular expertise requiring exacting knowledge about how the sun move across the sky during any given day or how the sun position in the sky changes throughout the year because the sun will always be exposed to some of the solar collection surfaces. A convex seven-surfaced square solar panel (not show) may also be used. In addition, the solar panel 70 may include a square horizontal border for collection (similar to border 95). Further, the solar panel is not limited to seven surfaces and various variations and combinations thereof can be used.

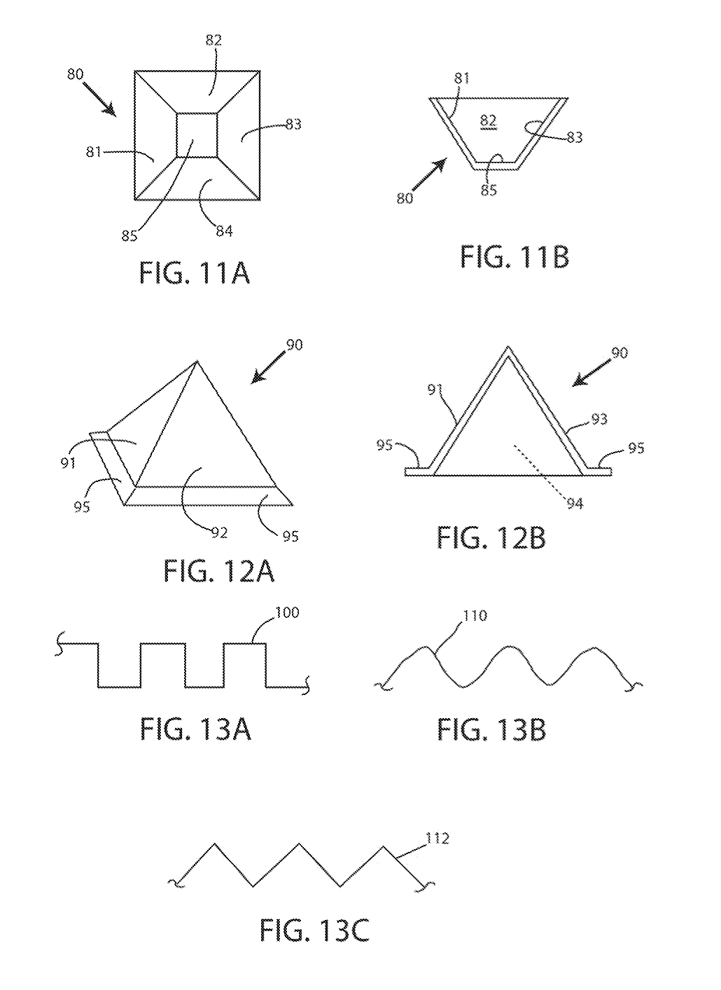

Referring now to FIGS. 11A and 11B, a concave five-surfaced square solar panel 80 is shown. The solar panel 80 is designed such that the various solar collection surfaces 81-85 will collect the sun's rays in an efficient manner as the sun moves across the sky. Since the solar panel 80 has solar collection surfaces arranged 360 degrees around the solar panel 80, the solar panel 80 can be installed with out particular expertise requiring exacting knowledge about how the sun move across the sky during any given day or how the sun position in the sky changes throughout the year because the sun will always be exposed to some of the solar collection surfaces. A convex five-surfaced square solar panel (not show) may also be used. In addition, solar panel 80 can include a horizontal square border similar to the boarder 95 of solar panel 90 and shown in FIGS. 12A and 12B. Further, the solar panel is not limited to five surfaces and various variations and combinations thereof can be used. As a variation, surface 81-84 could be made vertical, without being sloped, which would result in a cube shaped panel.

Referring now to FIGS. 12A and 12B, a convex pyramidal solar panel 90 is shown. The solar panel 90 is designed such that the various solar collection surfaces 91-95 will collect the sun's rays in an efficient manner as the sun moves across the sky. Since the solar panel 90 has solar collection surfaces arranged 360 degrees around the solar panel 90, the solar panel 90 can be installed with out particular expertise requiring exacting knowledge about how the sun move across the sky during any given day or how the sun position in the sky changes throughout the year because the sun will always be exposed to some of the solar collection surfaces. A convex pyramidal solar panel (not show) may also be used.

Referring now to FIG. 15, a concave spherical solar panel 120 is shown. The solar panel 120 is designed such that the curved solar collection surface 122 and the horizontal square border surface 123 (similar to border 95) will collect the sun's rays in an efficient manner as the sun moves across the sky. Since the solar panel 120 has solar collection surfaces 122 and 123 arranged 360 degrees around the solar panel 120, the solar panel 120 can be installed with out particular expertise requiring exacting knowledge about how the sun move across the sky during any given day or how the sun position in the sky changes throughout the year because the sun will always be exposed to some portion of the solar collection surface. A convex spherical solar panel (not show) may also be used. In addition, the curved shape does not have to be limited to a circular sphere, other curved shapes such as a parabolic or an elliptical shape can be used, and the solar panel can even be cone shaped.

Referring now to FIGS. 18A and 18B, a saw tooth shaped solar panel 150 is shown. The solar panel 150 is designed such that there are an increased number of solar collection surfaces 151-155 that will collect the sun's rays in an efficient manner as the sun moves across the sky. As can be seen, the solar panel 150 has thirteen surfaces for collecting the solar radiation. Solar panel 150 is in some respects similar to several of solar panels 10 or 20 connected together. Thus, solar panel 150 includes both concave and convex surfaces. In addition, any of the above described solar panel shapes could be used to form solar panel with an increased number of collection surfaces.

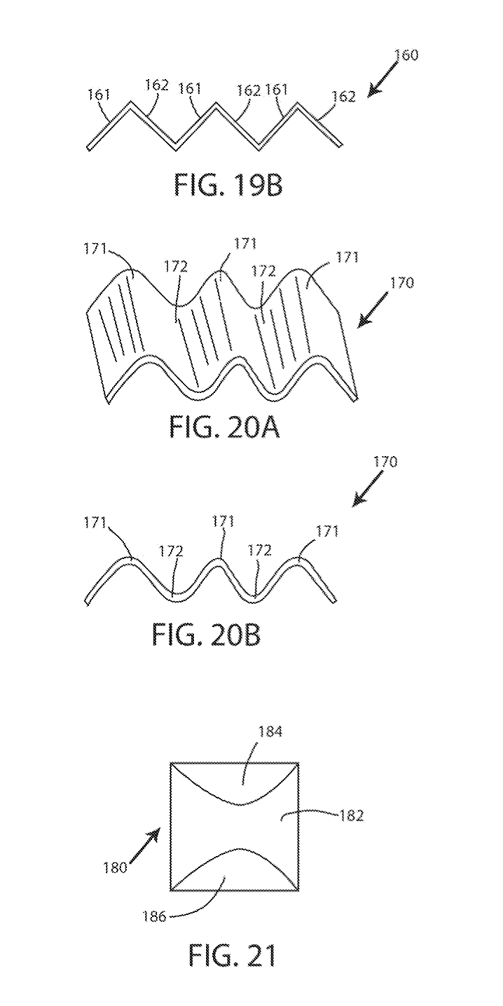

Referring now to FIGS. 19A and 19B, an accordion shaped solar panel 160 is shown. The solar panel 160 is designed such that there are an increased number of solar collection surfaces 161 and 162 that will collect the sun's rays in an efficient manner as the sun moves across the sky. As can be seen, the solar panel 160 has six surfaces for collecting the solar radiation. Solar panel 160 includes both concave and convex collection surfaces.

Referring now to FIGS. 20A and 20B, an undulating shaped solar panel 170 is shown. The solar panel 170 is designed such that there are an increased number of solar collection surfaces 171 and 172 that will collect the sun's rays in an efficient manner as the sun moves across the sky. As can be seen, the solar panel 170 has both concave and convex collection surfaces.

Referring now to FIG. 21, a saddle shaped solar panel 180 is shown. The solar panel 180 is designed such that the collection surfaces 182, 184, and 186 will collect the sun's rays in an efficient manner as the sun moves across the sky. Since the solar panel 180 has solar collection surfaces 182, 184, and 186 arranged 360 degrees around the solar panel 180, the solar panel 180 can be installed with out particular expertise requiring exacting knowledge about how the sun move across the sky during any given day or how the sun position in the sky changes throughout the year because the sun will always be exposed to some portion of the solar collection surface. In addition, the solar panel 180 may include a square horizontal border for collection (similar to border 95). The solar panel 180 may be concave or convex.

Referring now to FIGS. 13A-13C, individual solar cells 100, 110, and 112 are shown. The surface of the individual solar cell can be “textured” in order to increase the surface area on each cell. Thus, not only the solar panels can be shaped to increase capture of the sun's rays and increase the surface area of the panels, the cells themselves can also be shaped to increase the capture of the sun's rays and increase the surface area of the solar cells. Having a textured, or raised, surface provides the solar cells with a greater surface area. The vertical, angled, and curved surface of cells 100, 110, and 112, respectively, allow for capture of the sun's rays even when it is low in the sky. Thus, for example, the flat collection surface 91 can have textured solar cells in any of the shapes 100, 110, and 112. Therefore, each collection surface on any of the above described solar panels can have textured or three-dimensional solar cells. Further, each collection surface is not limited to one particular solar cell shape and it can have multiple combinations and variations of different shapes.

The shapes of the solar cells are not limited to the shapes shown in FIGS. 13A-13C, but all of the above described shapes of the solar panels could also describe the shape of the individual solar cells. For example, the solar cells could have a pyramidal shape similar to that shown in FIGS. 12A and 12B or have a spherical shape similar to that shown in FIG. 15. Thus, with solar cells formed in these shapes, the collection surfaces would have a bumpy, three-dimensional textured surface. This helps increase the surface area of the solar cells and the angles at which solar radiation is collected. If the solar cells were manufactured having the shapes shown in FIGS. 10, 11, 12, 15, and 21 (either convex or concave), the solar collection surfaces would have a bumpy surface. If the solar cells were manufactured having the shapes shown in FIGS. 4-9 (either convex or concave), the solar collection surfaces would have a ridged surface. These textured collection surfaces can be incorporated into a solar panel of any shape, included a flat solar panel.

Referring now to FIGS. 16A and 16B, a solar panel 130 on a moveable mount is shown. The solar panel is mounted on a pivoting mount 132 which can be controlled by a servo motor. The pivoting mount allows the solar panel 130 to move completely from side to side. The pivoting mount 132 is connected to an arm 134, which is connected to a base 138 via a rotating mount 136. The rotating mount 136, which can be controlled by a servo motor, can rotate the arm 134 in a full 360 degree circle. Thus, the solar panel 130 can be moved to track the position of the sun as it moves across the sky during the day and throughout the year. A flat solar panel 130 is shown, but any of the above described solar panel shapes may be used.

The solar tracking can be preprogrammed based on the known position of the sun at a given latitude. Thus, the time, date, and global position can be entered into a controller and the solar panel will automatically track the position of the sun throughout the day and the year. Further, anyone of the above described shaped solar panels can be used and the tracker can be optimized based on the shape of the solar panel used so that the most efficient use of the solar collecting surfaces of the shaped solar panel can be utilized.

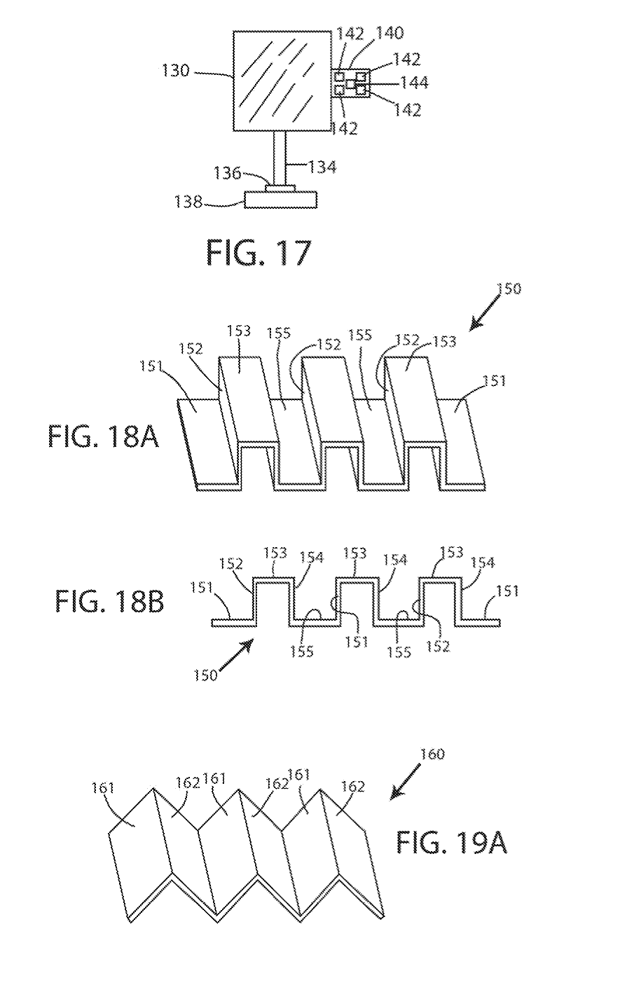

Alternatively, a photodetector array 140 can be attached to the solar panel 130, as shown in FIG. 17. The photodetector array 140 can include a plurality of peripheral sensors 142 and central sensor 144. The central sensor 144 is mounted and aligned with the solar panel 130 such that when the central sensor 144 receives the maximum solar radiation, the solar panel 130 is also receiving maximum solar radiation. If the solar radiation at any of the peripheral sensors 142 is greater than the central sensor 144, this means that the sun has moved so that the solar panel is no longer receiving maximum solar radiation. Thus, a controller can adjust the angle of the solar panel 130 such that the central sensor 144 is receiving the maximum radiation, which corresponds to maximum radiation on the solar panel 130.

These various shapes and constructions panels can used to collect solar energy for conversion into electricity, such as in photovoltaic layers 1400, as well as collection of solar energy for thermal heat, which can used heating liquids or gas (e.g., solar water heater applications), such as in thermal layers 1300 of the hybrid solar power system 1000.

Thus, while there have been shown, described, and pointed out fundamental novel features of the invention as applied to several embodiments, it will be understood that various omissions, substitutions, and changes in the form and details of the illustrated embodiments, and in their operation, may be made by those skilled in the art without departing from the spirit and scope of the invention. Substitutions of elements from one embodiment to another are also fully intended and contemplated. The invention is defined with regard to the claims appended hereto, and equivalents of the recitations therein.

We claim:

1. A hybrid solar power system, comprising:
an enclosure having at least one reflective surface;
at least one cover having at least one optical feature;
at least one thermal layer disposed in the enclosure, each of the at least one thermal layer having a plurality of thermal conduits; and
at least one layer of photovoltaic solar cells disposed in the enclosure, each of the at least one layer of photovoltaic cells having a plurality of photovoltaic cells,
wherein the at least one layer of thermal tubing and the at least one layer of photovoltaic solar cells are configured so that both layers are exposed to an incident light.

2. The hybrid solar power system as recited in claim 1, wherein the at least one optical feature includes a prism.

3. The hybrid solar power system as recited in claim 1, wherein the at least one optical feature includes a magnifying lens.

4. The hybrid solar power system as recited in claim 1, wherein the at least one optical feature is on a microscopic scale.

5. The hybrid solar power system as recited in claim 1, wherein the enclosure and the at least one reflective surface of the enclosure are configured to reflect the incident light so that the at least one thermal layer and the at least one layer of photovoltaic solar cells are both exposed to a reflected light.

6. The hybrid solar power system as recited in claim 1, wherein the cover is transparent.

7. The hybrid solar power system as recited in claim 1, wherein the at least one thermal layer is transparent.

8. The hybrid solar power system as recited in claim 1, wherein the at least one layer of photovoltaic solar cells is transparent.

9. The hybrid solar power system as recited in claim 1, wherein the plurality of photovoltaic cells includes a high-surface area solar panel.

10. The hybrid solar power system as recited in claim 1, wherein the plurality of thermal conduits include at least one optical feature.

11. The hybrid solar power system as recited in claim 1, wherein the at least one thermal layer includes a high-surface area solar panel.
